(19) United States
(12) Patent Application Publication
(10) Pub. No.: US 2014/0073908 A1
(43) Pub. Date: Mar. 13, 2014

(54) MAGNETIC RESONANCE IMAGE RECORDING UNIT AND A MAGNETIC RESONANCE DEVICE HAVING THE MAGNETIC RESONANCE IMAGE RECORDING UNIT

(71) Applicant: Stephan Biber, Erlangen (DE)

(72) Inventor: Stephan Biber, Erlangen (DE)

(21) Appl. No.: 14/025,990

(22) Filed: Sep. 13, 2013

(30) Foreign Application Priority Data
Sep. 13, 2012 (DE) 102012216303.4

(51) Int. Cl. G01R 33/563

(52) U.S. Cl. CPC G01R 33/56308
USPC 600/415; 324/322

(57) ABSTRACT

A magnetic resonance image recording unit for recording at least part of a patient during a magnetic resonance examination is presented. The magnetic resonance image recording unit has a first housing wall, a patient receiving area which is at least partially enclosed by the first housing wall, and a motion sensor unit for detecting a movement of the patient. The motion sensor unit has at least one motion sensor element which is arranged in a section of a side of the first housing wall facing away from the patient receiving area.

### CROSS REFERENCE TO RELATED APPLICATIONS

This application claims priority to German application No. 10 2012 216 303.4 DE filed Sep. 13, 2012, the entire content of which is hereby incorporated herein by reference.

### FIELD OF INVENTION

The present invention relates to a magnetic resonance image recording unit for recording at least part of a patient during a magnetic resonance examination, the magnetic resonance image recording unit having a first housing wall, a patient receiving area which is at least partially enclosed by the first housing wall, and a motion sensor unit for detecting a movement of the patient.

### BACKGROUND OF INVENTION

For magnetic resonance imaging it is important that a patient executes no movements for the entire duration of the magnetic resonance measurement. Movements of the patient during the magnetic resonance measurement can produce artifacts in the magnetic resonance images which subsequently, during a medical assessment of the magnetic resonance images, can lead to a misinterpretation and/or a reduction in informative significance. It can furthermore happen that the magnetic resonance measurement has to be repeated. In particular in the case of magnetic resonance measurements of claustrophobically inclined patients and/or pain patients and/or children, it is often difficult for the patient to remain lying motionless for the duration of the magnetic resonance measurement.

Methods are already known in which a movement of the patient's body is registered by means of the magnetic resonance measurement and subsequently a change in an execution of a measurement sequence is made, such as an adjustment of a gradient plane for example. However, methods of this kind must be developed individually for each magnetic resonance sequence.

Furthermore, it is known to detect the movement of the patient by means of a sensor unit. Thus, for example, in http://www.eng.hawaii.edu/college-events/2012-events/Ernst-MRImotionCorrection.pdf a method is disclosed in which additional marker elements are positioned on the patient, although this can lead to an increased workload for operating personnel.

Also known from Oline Olesen et al.: “Motion tracking for medical imaging: a nonvisible structured light tracking approach”, IEEE Trans. On Med. Imaging, January 2012, is a method in which a movement of the patient is detected by means of an optical stripe projection. However, this method can be implemented only with difficulty due to a constriction in for example a head coil unit. Furthermore, this method has only insufficient precision in detecting the motion.

### SUMMARY OF INVENTION

The object underlying the present invention is in particular to enable a motion sensor unit to be integrated within a magnetic resonance image recording unit in a particularly simple and space-saving manner. The object is achieved by means of the features of the independent claims. Advantageous embodiments are described in the dependent claims.

The invention proceeds from a magnetic resonance image recording unit for recording at least part of a patient during a magnetic resonance examination, the magnetic resonance image recording unit having a first housing wall, a patient receiving area which is at least partially enclosed by the first housing wall, and a motion sensor unit for detecting a movement of the patient.

It is proposed that the motion sensor unit has at least one motion sensor element which is arranged in a section of a side of the first housing wall facing away from the patient receiving area, as a result of which the motion sensor unit, in particular the at least one motion sensor element of the motion sensor unit, can be integrated in a particularly space-saving and constructionally simple manner within the magnetic resonance image recording unit. Moreover, this enables an in particular spatial encroachment on the patient inside the patient receiving area due to the motion sensor unit to be advantageously prevented.

What is to be understood by a magnetic resonance image recording unit in this context is in particular a unit which is configured to allow an at least partial recording of the patient for a magnetic resonance examination. Preferably the magnetic resonance image recording unit is formed by a magnetic resonance coil device. Alternatively or in addition to a magnetic resonance coil device, the magnetic resonance image recording unit can also be formed by a patient positioning device on which the patient is placed during the magnetic resonance examination. The first housing wall of the magnetic resonance coil device at least partially encloses the patient receiving area. The first housing wall can also include a positioning surface for positioning the patient, as can be advantageous for example in an embodiment of the magnetic resonance image recording unit as a patient positioning device. An at least partially closed-off installation space of the magnetic resonance image recording unit is preferably arranged on a side of the first housing wall facing away from the patient receiving area, said installation space being configured for accommodating further units, for example radio-frequency antenna elements, etc. Preferably the motion sensor unit, in particular the at least one motion sensor element, is arranged after the first housing wall in such a way that a focus of the at least one sensor element is directed onto the patient receiving area. The motion sensor unit can include all motion sensor units deemed useful by the person skilled in the art, such as an optical motion sensor unit, for example, which can comprise a camera and/or a laser system and/or a stripe projection unit and/or an infrared unit and/or a radar unit, etc.

It is furthermore proposed that the first housing wall has at least one transparent subsection which is arranged along a radiation path from the patient to the at least one motion sensor element upstream of the at least one motion sensor element. This advantageously enables a movement of the patient during the magnetic resonance examination to be detected in spite of the arrangement of the motion sensor unit in a region of the magnetic resonance image recording unit which is arranged on a side of the first housing wall facing away from the patient receiving area. The at least one radiolucent and/or transparent subsection of the first housing wall can include a radiolucent and/or transparent window and is preferably formed from a transparent material, such as from a polycarbonate, for example, and/or a glass material, etc. It is furthermore conceivable that the radiolucent and/or transparent subsection is formed by a cutout within the first housing wall.

The at least one transparent subsection is particularly advantageously embodied as transparent and/or radiolucent to radiation emitted by the motion sensor unit and/or radiation to be received from the motion sensor unit, thereby ensuring that an undesirable beam attenuation and/or beam deflection of the radiation emitted by the at least one motion sensor element and/or of the beams to be received can be prevented. For example, the at least one radiolucent and/or transparent subsection of the first housing wall can be embodied as transparent and/or permeable to infrared radiation and/or radiation from visible light, etc.

In an advantageous development of the invention it is proposed that the at least one transparent subsection of the first housing wall is at least partially encompassed by imaging optics of the motion sensor unit, thereby enabling in particular further components and/or installation space in the embodiment of the imaging optics to be saved. In this case the at least one transparent subsection of the first housing wall advantageously at least partially includes a curved surface. Alternatively or in addition, the at least one transparent subsection can also have further optical elements having other optical properties, such as for example an optical filter, etc.

The first housing wall having the at least one transparent subsection can be manufactured in a particularly simple manner if the first housing wall is formed at least in part of a transparent material and a nontransparent subsection of the first housing wall has a nontransparent coating. For example, the radiation-impermeable and/or nontransparent coating can comprise a radiation-impermeable and/or nontransparent film, in particular a radiation-impermeable and/or nontransparent adhesive film, and/or a radiation-impermeable and/or nontransparent coating of lacquer, etc.

In a further embodiment of the invention it is proposed that the motion sensor unit has at least two motion sensor elements, the first motion sensor element having a first field of view and the second motion sensor element having a second field of view and the two fields of view being embodied and/or arranged differently from one another. By a field of view of a motion sensor element in this context is to be understood in particular an optical region detected by the motion sensor element along an optical axis of the motion sensor element. By means of this embodiment of the invention the patient can advantageously be monitored from different perspectives with regard to a movement of the patient. Furthermore, the movement of the patient can be detected particularly reliably and/or precisely by this means.

In addition it is proposed that the first housing wall has at least two transparent subsections, with one of the motion sensor elements in each case being arranged in a section of a side of one of the at least two transparent subsections facing away from the patient receiving area, as a result of which each of the motion sensor elements has an advantageous optical access to the patient receiving area, more particularly to the patient inside the patient receiving area. Alternatively hereto, the different motion sensor elements can also be arranged in a section of a side of a single transparent subsection facing away from the patient receiving area.

It is furthermore proposed that the motion sensor unit has at least one adjustment unit for adjusting a field of view of the at least one motion sensor element, thereby enabling the field of view, in particular an optical axis of the field of view, of the at least one motion sensor element to be changed and/or adjusted. In this way the optical axis can be aligned with a possible motion region and/or a region relevant to the magnetic resonance examination inside the patient receiving area and consequently a possible movement can be detected particularly precisely. In this arrangement the adjustment unit can include mechanically and/or electronically adjustable adjustment elements.

Particularly advantageously, the motion sensor unit has at least one zoom unit by means of which a motion region can advantageously be focused on during a magnetic resonance examination. The motion sensor unit preferably has a plurality of adjustment units and/or zoom units, such that a separate adjustment and/or separate focusing can be effected for each of the motion sensor elements by means of a separate adjustment unit and/or zoom unit.

The invention also proceeds from a patient positioning device having a magnetic resonance image recording unit as claimed in one of claims 1 to 10, wherein the first housing wall includes a positioning surface for positioning the patient. Owing to the dimensions of the positioning surface, the entire body of the patient can be monitored with regard to an undesirable movement in this case during the magnetic resonance measurement. This furthermore enables the motion sensor unit to be integrated within the patient positioning device in a particularly space-saving and constructionally simple manner and at the same time a spatial encroachment on the patient on the patient positioning device due to the motion sensor unit to be advantageously prevented.

The invention also proceeds from a magnetic resonance coil device having a magnetic resonance image recording unit as claimed in one of claims 1 to 10. By virtue of the inventive embodiment a movement of the patient in a region of the patient relevant to the magnetic resonance examination can advantageously be detected. Furthermore, the motion sensor unit can be integrated in a particularly space-saving and constructionally simple manner within the magnetic resonance coil device and at the same time a spatial encroachment on the patient inside the patient receiving area due to the motion sensor unit can advantageously be prevented. Preferably the magnetic resonance coil device has a second housing wall, the second housing wall shielding the magnetic resonance coil device toward the outside. Radio-frequency antenna elements are preferably arranged between the first and the second housing wall of the magnetic resonance coil device. The at least one motion sensor element of the motion sensor unit is arranged between the first and the second housing wall of the magnetic resonance coil device.

What is to be understood by a magnetic resonance coil device in this context is in particular a radio-frequency coil device, which is preferably used in conjunction with a magnetic resonance device. The magnetic resonance coil device can be formed by a radio-frequency antenna unit permanently installed within the magnetic resonance device or by a local magnetic resonance coil device which can be used in conjunction with the magnetic resonance device only for specific applications and/or magnetic resonance examinations. In this case the local magnetic resonance coil device can be formed for example by a head coil unit, a knee coil unit, an arm coil unit, etc. The first housing wall of the magnetic resonance coil device at least partially encloses the patient receiving area. For example, the first housing wall of a knee coil unit encloses the patient receiving area in the manner of a cylinder, the first housing wall of a head coil unit encloses the patient receiving area in the manner of a skull cap, etc., the first housing wall directly enclosing the patient receiving area.

The invention also proceeds from a magnetic resonance coil device comprising a main magnet, a gradient coil unit, a radio-frequency coil unit, a patient positioning device and a magnetic resonance image recording unit as claimed in one of claims 1 to 10. This advantageously enables an undesirable movement of the patient during a magnetic resonance examination to be detected and said movement to be forwarded directly to an evaluation unit and/or a control unit of the magnetic resonance device so that a current movement of the patient can be taken into account in a measurement sequence during the magnetic resonance measurement and/or for evaluation of the measured magnetic resonance data. Moreover, the motion sensor unit, in particular the at least one motion sensor element of the motion sensor unit, can be integrated in a particularly space-saving and constructionally simple manner within the magnetic resonance device. By this means an in particular spatial encroachment on the patient within the patient receiving area due to the motion sensor unit during a magnetic resonance examination can advantageously be prevented.

It is furthermore proposed that the radio-frequency antenna unit comprises the magnetic resonance image recording unit. Preferably the radio-frequency coil unit is formed by a magnetic resonance coil device permanently installed inside the magnetic resonance device, in particular inside a magnet unit of the magnetic resonance device. By means of this embodiment of the invention a movement of the patient can advantageously be detected independently of a subregion of the patient that is to be examined. Furthermore, the motion sensor unit is available for motion measurement for every magnetic resonance measurement.

Alternatively or in addition, a magnetic resonance coil device formed by a local coil device can also include the magnetic resonance image recording unit, thereby enabling a movement of the patient to be detected directly in a region relevant to the magnetic resonance measurement, in particular within the patient receiving area of the local coil device.

It can furthermore be provided that the patient positioning device includes the magnetic resonance image recording unit, thereby advantageously enabling any movement of the patient positioned on the patient positioning device to be detected.

### BRIEF DESCRIPTION OF THE DRAWINGS

Further advantages, features and details of the invention will emerge from the exemplary embodiments described below, as well as with reference to the drawings, in which:

FIG. 1 shows a magnetic resonance device in a schematic representation,

FIG. 2 shows a schematic section through a local magnetic resonance coil device having a magnetic resonance image recording unit,

FIG. 3 shows a schematic section through a radio-frequency antenna unit having a magnetic resonance image recording unit, and

FIG. 4 shows a schematic representation of a patient positioning device having a magnetic resonance image recording unit.

### DETAILED DESCRIPTION OF INVENTION

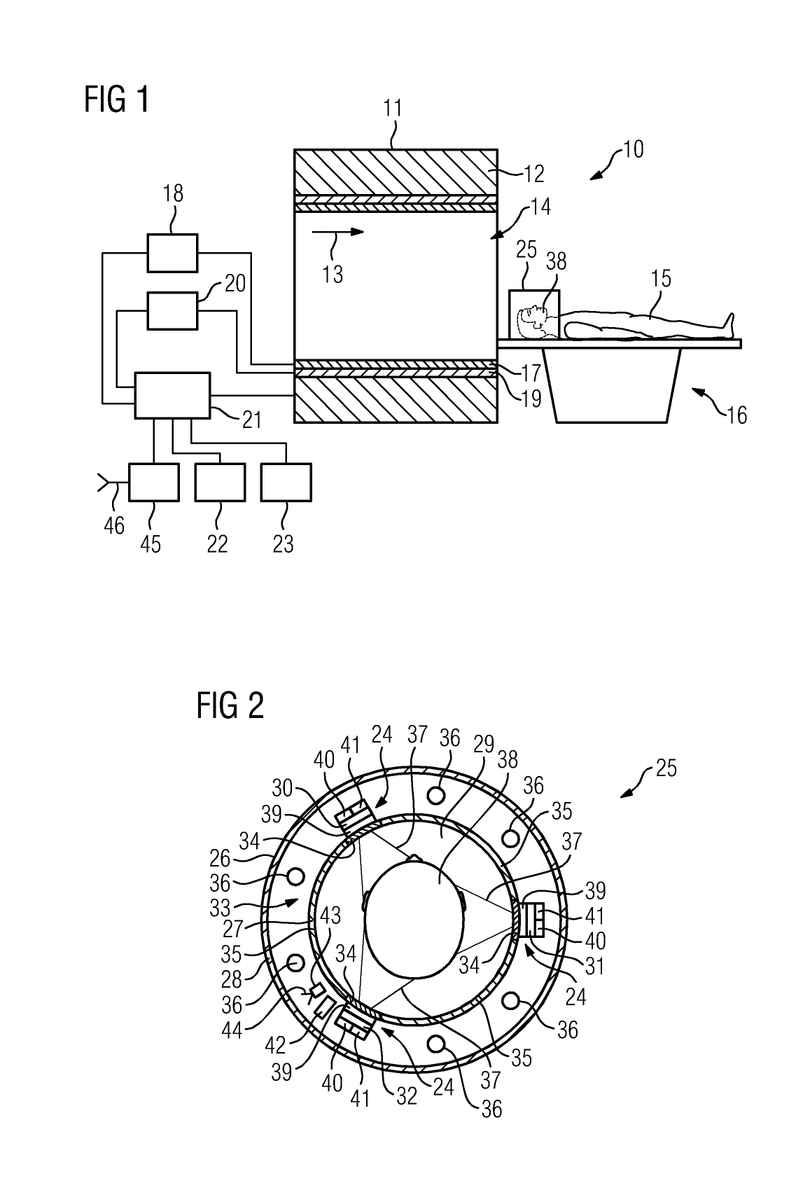

A magnetic resonance device 10 according to the invention is shown in FIG. 1. The magnetic resonance device 10 comprises a magnet unit 11 having a main magnet 12 for generating a strong, and in particular constant, main magnetic field 13. In addition, the magnetic resonance device 10 has a cylinder-shaped patient receiving area 14 for accommodating a patient 15, the patient receiving area 14 being enclosed by the magnet unit 11 in a circumferential direction. The patient 15 can be introduced into the patient receiving area 14 by means of a patient positioning device 16 of the magnetic resonance device 10.

The magnet unit 11 also has a gradient coil unit 17 for generating magnetic field gradients that are used for spatial encoding during an imaging session. The gradient coil unit 17 is controlled by way of a gradient control unit 18. In addition, the magnet unit 11 has a radio-frequency antenna unit 19 permanently integrated within the magnet unit 11 and a radio-frequency antenna control unit 20 for exciting a polarization which becomes established in the main magnetic field 13 generated by the main magnet 12. The radio-frequency antenna unit 19 is controlled by the radio-frequency antenna control unit 20 and radiates radio-frequency magnetic resonance sequences into an examination space which is substantially formed by the patient receiving area 14. This causes the magnetization to be deflected from its state of equilibrium.

In order to control the main magnet 12, the gradient control unit 18, and in order to control the radio-frequency antenna control unit 20, the magnetic resonance device 10 has a system control unit 21 formed by a computing unit. The system control unit 21 centrally controls the magnetic resonance device, such as the execution of a predetermined imaging gradient echo sequence, for example. Control information such as imaging parameters, for example, and reconstructed magnetic resonance images can be displayed on a display unit 22, for example a monitor, of the magnetic resonance device 10. In addition, the magnetic resonance device 10 has an input unit 23 by means of which information and/or parameters can be input by an operator during a measurement operation.

Furthermore, the magnetic resonance device 10 includes a motion sensor unit 24 for detecting a movement of the patient 15 during a magnetic resonance examination. The motion sensor unit 24 is illustrated in greater detail in FIG. 2. The motion sensor unit 24 is arranged inside a local magnetic resonance coil device, the local magnetic resonance coil device being formed in the present exemplary embodiment by a local head coil unit 25 for examinations at the head 38 of the patient 15. Alternatively hereto, the local magnetic resonance coil device can also be formed by a knee coil unit, an arm coil unit, a chest coil unit, etc.

The head coil unit 25 comprises a magnetic resonance image recording unit 26 for recording at least a part of the patient 15 for the magnetic resonance examination. The magnetic resonance image recording unit 26 comprises a first housing wall and a second housing wall, the first housing wall being formed by an inner housing wall 27 and the second housing wall being formed by an outer housing wall 28. The outer housing wall 28 shields the head coil unit 25 toward the outside and the inner housing wall 27 encloses a patient receiving area 29 of the head coil unit 25 or of the magnetic resonance image recording unit 26 in the manner of a skull cap.

The motion sensor unit 24 has a plurality of motion sensor elements 30, 31, 32 which are arranged in a section 33 of a side of the inner housing wall 27 facing away from the patient receiving area 29, and in particular are arranged between the inner housing wall 27 and the outer housing wall 28. For this purpose the inner housing wall 27 has radiolucent and/or transparent subsections 34 which are embodied as transparent and/or permeable to radiation emitted by the motion sensor unit 24, in particular by the individual motion sensor elements 30, 31, 32, and/or to radiation that is to be received by the motion sensor unit 24, in particular by the individual motion sensor elements 30, 31, 32. In this arrangement the radiolucent and/or transparent subsections 34 are formed from a radiolucent and/or transparent material, such as from a radiolucent and/or transparent plastic for example, e.g. a polycarbonate, and/or from a radiolucent and/or transparent glass material, etc.

The inner housing wall 27 also has radiation-impermeable and/or nontransparent subsections 35, the nontransparent subsections 35 likewise comprising the same transparent material as the radiolucent and/or transparent subsections 34 of the inner housing wall 27. In addition, the radiation-impermeable and/or nontransparent subsections 35 have a radiation-impermeable and/or nontransparent coating which can include for example a radiation-impermeable and/or nontransparent film, in particular a radiation-impermeable and/or nontransparent adhesive film, and/or a radiation-impermeable and/or nontransparent coat of lacquer, etc. Alternatively hereto, the radiation-impermeable and/or nontransparent subsections 35 of the inner housing wall 27 can also be formed from a radiation-impermeable and/or nontransparent material.

The head coil unit 25 additionally has radio-frequency coil elements 36 which are arranged in particular between the radiation-impermeable and/or nontransparent subsections 35 of the inner housing wall 27 and the outer housing wall 28. The radio-frequency coil elements 36 can for example include a coil detection unit and/or a detuning circuit and/or a matching circuit and/or a power supply lead and/or a voltage source and/or individual antenna elements, etc.

In the present exemplary embodiment the different motion sensor elements 30, 31, 32 of the motion sensor unit 24 are arranged in each case in a section of a side of the radiolucent and/or transparent subsections 34 of the inner housing wall 27 facing away from the patient receiving area 29, the inner housing wall 27 having a separately embodied, radiolucent and/or transparent subsection 34 for each of the motion sensor elements 30, 31, 32. Alternatively hereto, it can also be provided that the inner housing wall 27 comprises only a single radiolucent and/or transparent subsection 34 which extends over the different positioning surfaces of the plurality of motion sensor elements 30, 31, 32 on the inner housing wall 27.

The plurality of motion sensor elements 30, 31, 32 of the motion sensor unit 24 are arranged at different positions in the section 33 between the inner housing wall 27 and the outer housing wall 28. The individual motion sensor elements 30, 31, 32 each have an optical field of view 37, the optical fields of view 37 of the motion sensor elements 30, 31, 32 being different from one another, thus making possible a detection, by each of the motion sensor elements 30, 31, 32, of a perspective of the patient receiving area 29 and/or of the subregion of the patient 15, for example the head 38 of the patient 15, arranged inside the patient receiving area 29 that is different from the other motion sensor elements 30, 31, 32.

The plurality of motion sensor elements 30, 31, 32 of the motion sensor unit 24 are embodied in such a way that in each case the radiolucent and/or transparent subsection 34 of the inner housing wall 27 is encompassed by imaging optics 39 of the respective motion sensor element 30, 31, 32. Toward that end, the individual radiolucent and/or transparent subsections 34 have for example a curvature and/or a curved surface that is advantageous for detecting a movement of the patient 15. Furthermore, it can also be provided that only part of the radiolucent and/or transparent subsections 34 has a curved surface. In addition, a material of the radiolucent and/or transparent subsections 34 can also be selected with regard to an imaging characteristic of the respective motion sensor elements 30, 31, 32.

In the present exemplary embodiment the motion sensor unit 24 is formed by an optical motion sensor unit. For that purpose the individual motion sensor elements 30, 31, 32 are formed for example by a camera and/or a laser system and/or a stripe projection system and/or an infrared sensor element and/or a radar sensor element.

Furthermore, the motion sensor unit 24 has an adjustment unit 40 and a zoom unit 41 for each of the plurality of motion sensor elements 30, 31, 32. The optical field of view 37 and/or an optical axis of the respective motion sensor element 30, 31, 32 are/is adjusted by means of the adjustment units 40. For example, the individual optical fields of view 37 and/or the individual optical axes of the motion sensor elements 30, 31, 32 can be aligned and/or adjusted in such a way that the complete patient receiving area 29 of the head coil unit 25 can be monitored by means of the motion sensor elements 30, 31, 32 with regard to a movement of the patient 15 inside the patient receiving area 29. Alternatively hereto, the individual optical fields of view 37 and/or optical axes can also be directed onto a relevant examination region by means of the adjustment units 40, such that a movement of the patient 15 in said examination region of interest can be detected from different perspectives. The individual adjustment units 40 can in this case have mechanical adjustment means and/or electronic adjustment means.

By means of the zoom units 41 it is furthermore possible for each of the motion sensor elements 30, 31, 32 to focus on the subregion of the patient 15, in particular a surface of the patient 15, arranged inside the patient receiving area 29.

The adjustment units 40 and the zoom units 41 are controlled by a control unit 42 of the motion sensor unit 24. In addition, the motion sensor unit 24 comprises a data transmission unit 43 having an antenna element 44. The motion data acquired by the individual motion sensor elements 30, 31, 32 is transmitted via data transmission means (not shown in more detail) to the control unit 42 and the data transmission unit 43. The motion data of the patient 15 acquired by means of the motion sensor elements 30, 31, 32 is transmitted to the system control unit 21 wirelessly and/or cablelessly by means of the data transmission unit 43 and the antenna element 44, for which purpose the system control unit 21 has a data receiving unit 45 having an antenna element 46.

The motion data acquired by the motion sensor unit 24 is routed to the system control unit 21 and evaluated there. Alternatively hereto, the motion sensor unit 24 too can likewise have an evaluation unit for evaluating the acquired motion data. Depending on a movement of the patient 15, the currently running magnetic resonance measurement, for example, will be interrupted by the system control unit 21 and a restart of the magnetic resonance measurement will be initiated. Furthermore, it is also possible for example to repeat only a partial measurement of the entire magnetic resonance examination that is to be carried out on the patient 15. Moreover, it is also conceivable, when only slight movements of the patient 15 are detected, for the motion data to be taken into account only at the time of an evaluation of the magnetic resonance measurement.

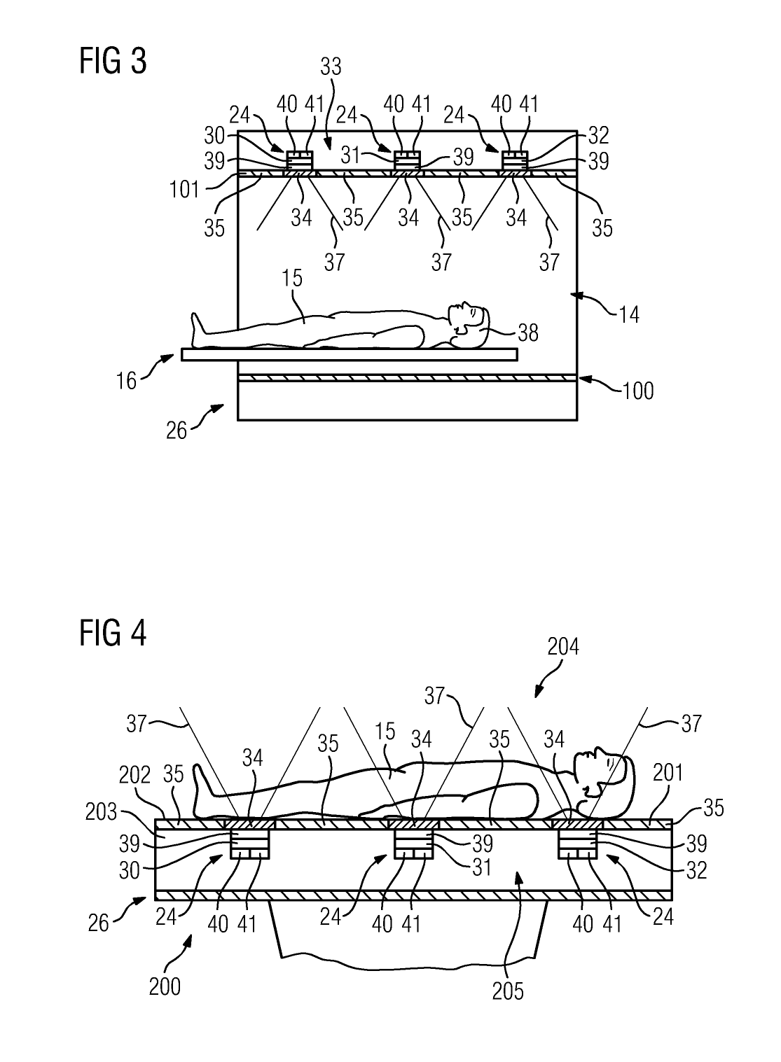

An arrangement of the magnetic resonance image recording unit 26 in an alternative exemplary embodiment to FIG. 2 is shown in FIG. 3. Components, features and functions remaining substantially the same are systematically labeled with the same reference numerals. The following description limits itself essentially to the differences compared to the exemplary embodiment shown in FIGS. 1 and 2, with reference being made to the description of the exemplary embodiment shown in FIGS. 1 and 2 in respect of like components, features and functions.

The magnetic resonance image recording unit 26 in FIG. 3 is likewise encompassed by a magnetic resonance coil device, though the magnetic resonance coil device is formed by the radio-frequency antenna unit 100 permanently integrated within the magnet unit 11. The radio-frequency antenna unit 100 also has a first housing wall 101 which is formed by an inner housing wall and has radiolucent and/or transparent subsections 34. Furthermore, the inner housing wall encloses the patient receiving area 14 of the magnetic resonance device 10 in the manner of a cylinder. The radio-frequency antenna unit 100 additionally has radio-frequency antenna elements (not shown in further detail).

The motion sensor unit 24 is embodied analogously to the description relating to FIG. 2 and is arranged, also analogously to the description, within the radio-frequency antenna unit 100.

An arrangement of the magnetic resonance image recording unit 26 in an alternative exemplary embodiment to FIG. 2 is shown in FIG. 4. Components, features and functions remaining substantially the same are systematically labeled with the same reference numerals. The following description limits itself essentially to the differences compared to the exemplary embodiment shown in FIGS. 1 and 2, with reference being made to the description of the exemplary embodiment shown in FIGS. 1 and 2 in respect of like components, features and functions.

The magnetic resonance image recording unit 26 in FIG. 4 is encompassed by the patient positioning device 200. In this arrangement the patient positioning device 200 has a first housing wall 201 which is encompassed by a positioning surface 202 of a positioning table 203 of the patient positioning device 200 for positioning the patient 15. The positioning surface 202 of the patient positioning device 200 has radiolucent and/or transparent subsections 34, the motion sensor unit 34, in particular the individual motion sensor elements 30, 31, 32 of the motion sensor unit 24. The positioning surface 202 delimits a patient receiving area 204 formed by a patient positioning area in a downward direction. The motion sensor unit 24, in particular the individual motion sensor elements 30, 31, 32 of the motion sensor unit 24, are arranged in a section 205 of a side of the first housing wall 201 facing away from the patient receiving area 204.

The motion sensor unit 24 is embodied analogously to the description relating to FIG. 2 and is arranged, also analogously to the description, inside the patient positioning device 200.

1. A magnetic resonance image recording unit for recording at least part of a patient during a magnetic resonance examination, comprising:
a first housing wall;
a patient receiving area that is at least partially enclosed by the first housing wall; and
a motion sensor unit for detecting a movement of the patient,
wherein the motion sensor unit comprises at least one motion sensor element that is arranged in a section of a side of the first housing wall facing away from the patient receiving area.

2. The magnetic resonance image recording unit as claimed in claim 1, wherein the first housing wall comprises at least one transparent subsection.

3. The magnetic resonance image recording unit as claimed in claim 2, wherein the at least one transparent subsection is transparent to a radiation emitted by the motion sensor unit and/or a radiation that is to be received by the motion sensor unit.

4. The magnetic resonance image recording unit as claimed in claim 2, wherein the at least one transparent subsection is at least partially encompassed by imaging optics of the motion sensor unit.

5. The magnetic resonance image recording unit as claimed in claim 2, wherein the at least one transparent subsection at least partially comprises a curved surface.

6. The magnetic resonance image recording unit as claimed in claim 1, wherein the first housing wall is at least partially formed from a transparent material and a nontransparent subsection of the first housing wall comprises a nontransparent coating.

7. The magnetic resonance image recording unit as claimed in claim 1, wherein the motion sensor unit comprises at least two motion sensor elements, wherein the first motion sensor element comprises a first field of view and the second motion sensor element comprises a second field of view, and wherein the first and the second fields of view are arranged differently from one another.

8. The magnetic resonance image recording unit as claimed in claim 7, wherein the first housing wall comprises at least two transparent subsections, wherein the at least two motion sensor elements are arranged respectively in a section of a side of one of the at least two transparent subsections facing away from the patient receiving area.

9. The magnetic resonance image recording unit as claimed in claim 1, wherein the motion sensor unit comprises at least one adjustment unit for adjusting a field of view of the at least one motion sensor element.

10. The magnetic resonance image recording unit as claimed in claim 1, wherein the motion sensor unit comprises at least one zoom unit.

11. A patient positioning device, comprising:
a magnetic resonance image recording unit as claimed in claim 1,
wherein the first housing wall comprises a positioning surface for positioning the patient.

12. A magnetic resonance device, comprising:
a main magnet;
a gradient coil unit;
a radio-frequency antenna unit; and
a magnetic resonance image recording unit as claimed in claim 1 .

13. The magnetic resonance device as claimed in claim 12, wherein the radio-frequency antenna unit comprises the magnetic resonance image recording unit.

14. The magnetic resonance device as claimed in claim 12, wherein a local coil device comprises the magnetic resonance image recording unit.

15. The magnetic resonance device as claimed in claim 12, wherein a patient positioning device comprises the magnetic resonance image recording unit.
